(19) United States
(12) Patent Application Publication
(10) Pub. No.: US 2012/0180849 A1
(43) Pub. Date: Jul. 19, 2012

(54) Solar concentrator tent system

(76) Inventors: Brent Alen Bettencourt, Walnut Creek, CA (US); Peter Stuart Lynn, Oakland, CA (US)

(21) Appl. No.: 13/374,805

(22) Filed: Jan. 13, 2012

Related U.S. Application Data
(60) Provisional application No. 61/432,556, filed on Jan. 13, 2011.

(51) Int. Cl. H01L 31/058

(52) U.S. Cl. 136/248

(57) ABSTRACT

A low cost transparent tent that captures and concentrates solar energy by enclosing and shielding subsystems from wind and weather, thereby enabling heat and or electricity for less than the cost of energy derived from combusting coal. The solar concentrating tent is also capable of supporting photocatalytic reactions to produce hydrogen, high value hydrocarbons and clean water. The solar concentrator tent system can be erected in minutes without substantial skill and does not require ground or surface preparation.

### CROSS REFERENCE TO RELATED APPLICATIONS

This application claims the benefit of provisional patent application Ser. No. 61/432,556, filed 2011 Jan. 13 by the inventors.

### BACKGROUND

The global solar energy resource is around 89,000 TW and the global wind resource is around 370 TW, while global energy consumption is around 15 TW. Solar energy dwarf's all other alternative energy resources and has the potential to supply all of humanity's energy needs many times over without substantial environmental disruption. Solar energy is the most likely contender in transitioning from a fossil fuel energy economy to one based on alternative energy. To achieve this, cost must come down significantly, to a level comparable with energy derived from fossil fuel sources, and then a tipping point might be passed.

The cost effectiveness of solar power is largely limited by power density; only so much energy per square meter is available from the sun. Consequently, solar power systems are largely constrained by their per square meter cost. Solar concentrators attempt to lower this cost by using a cheaper mirror or lens to concentrate the solar energy onto a much smaller area, greatly increasing its intensity and usefulness. For example, a solar cell that produces 1 watt in normal sunlight might produce 25 Watts when the sunlight is concentrated upon it 25 times over, hence the attraction of solar concentration. Thus a low cost solar concentration system has the potential to dramatically reduce the cost of solar power and thereby make it commercially competitive with energy derived from fossil fuels.

Solar concentrator systems, whether for photovoltaics or solar thermal power generation, generally consist of heavy mirrors and high strength actuation systems capable of withstanding high wind loadings with accuracy. Lightweight inflatable or stretched membrane concentrator systems are possible, however surfaces will deflect under wind loadings—this is not conducive to high optical accuracy. The greater the solar concentration ratio, the greater the accuracy required. These aerodynamic forces can be as high as 50 kg/m² in a 100 km/hr wind, and may vary dramatically with every gust perhaps inducing oscillations that further inhibit accuracy. Eliminating the small deflections of the lightweight membrane surfaces under such conditions is next to impossible, as this leads to various design compromises. Also, the aerodynamically induced solar tracking power and structural requirements for an inflatable or stretched membrane concentrator are little different to that of a heavy and expensive rigid concentrator system.

Solar concentrators constructed from very thin reflective films held in tension; whether by inflation, a rigid support structure or centripetal loads, have for many decades been suggested for providing solar power in space, and also on the moon. Some of the concentrator designs suggested have weighed only a few grams per square meter and been many kilometers across. Such extremely lightweight construction is made possible by the absence of terrestrial weather including wind, rain, hail, dust and snow.

Lightweight tents that protect that within from the weather are ubiquitous and have been so for millennia. They have proved effective on every continent and in the most inhospitable of environments. With the modem era, tent designs that are very lightweight, very low cost, and that can withstand extreme weather have become common. Modern tent designs can also be very quick to pitch and pack away, and transparent flexible plastic windows have also become practical for such tents. Tents can also pack into very small volumes; combined with their lightweight this can make them very convenient and inexpensive to transport.

Modern windsurfing sails often use transparent Mylar films of around 0.125 millimeters in thickness or 0.175 kilograms per square meter. The surfaces of some windsurfing sails are made predominantly from clear Mylar. Windsurfing sails are designed to sustain very high wind loadings and significant physical abuse; they often have to survive being caught in large surf. Lightweight and low cost transparent films do survive high wind loadings and many construction systems and techniques have been developed for using them in such applications.

The bulk cost of the polyester that is used for Mylar films is around $1.25 per kilogram. The bulk cost of polycarbonate that is used to make similar polycarbonate films is around $2.50 per kilogram. Polycarbonate films have far better UV resistance than Mylar films with outdoor longevities of twenty years possible. Other low cost plastic films are also available. With film weights of around 0.175 kilograms per square meter the cost of these films can be very low, potentially as little as $1 per square meter. This enables the construction of very low cost wind resistant structures.

Solar concentration dates back millennia and the general idea of using a solar concentrator inside, protected from the weather, is far from new. Many young children have entertained themselves by sitting in front of a sunny window with a magnifying glass, and perhaps a piece of paper or a poor helpless insect. With modern technologies including microelectronics, photo voltaics and low cost thin film materials, great advances are now possible with weather protected solar concentrators.

### SUMMARY

An ultra-lightweight thin film parabolic trough solar concentrator is protected and shielded from wind by a low cost transparent tent enclosure solving many of the economic and installation problems faced by current concentrator based systems. This very lightweight structure enables a system, which is much lighter and much lower in cost for a given area and power output. This enables electricity generation for around $0.04/kWhr or less, which is lower than most all wholesale electricity derived from coal power stations. A solar thermal concentrating tent system can produce heat at an approximate cost of $0.001/kWhr.

The solar concentrator consists of a thin reflective film, which is stretched between parabolically curved ribs. Being lightweight, balanced and shielded from the wind, the concentrator can be accurately rotated to face the sun with very little force. It is possible to install such a concentrator for around $10 per square meter, including actuation and support systems.

Very simple tents are commercially available for recreational and survival purposes that stretch thin fabrics over a multitude of light weight support structures. Such tents are used on the top of Mount Everest, for example, and can sustain high wind and snow loadings. Transparent tents with useful lives of ten years or more with the ability to withstand 100 kilometer per hour winds and ultra-violet radiation can now be made for as little as $10 per square meter or less.

By separating the weather survival and solar concentrating requirements, low cost technology solar concentrator systems appear to be possible for around $20 per square meter installed, less than a fifth that of conventional rigid solar concentrators. If combined with 17% to 24% efficient mono-crystalline solar cells, and taking into account pointing errors and thermal effects, this equates to approximately 10% to 18% photon to electrical efficiencies for the solar concentrator tent system.

Concentration ratios of 25 are practical, 50 possible and 100 conceivable with a parabolic trough system consisting of a reflective film stretched between parabolically curved ribs, assuming it is shielded from wind. By adding a second stage concentrator system, overall concentration ratios in excess of a thousand are possible. Photovoltaic solar cells based upon Type III-V materials optimized for high solar concentration are now becoming available with conversion efficiencies near 40%. Installing the high efficiency Type III-V materials in the tent based solar concentrator will allow photon to electrical conversion efficiencies to exceed 30% when accounting for concentrator losses.

The solar concentrating tent will enable cost effective distributed solar power for both developed and undeveloped countries with benefits to include but not be limited to:

Solar electricity power at around $0.75/W and solar thermal heat at around $0.021W, depending on externalities.

Largely scale independent, with small systems possible that can be sold to individual households, commercial rooftops and military bases.

Around $0.04/kWhr electricity cost and $0.001/kWhr thermal energy cost, again depending on externalities, with this perhaps being the effective retail price for many direct users.

Hot water and or air are byproducts of the solar concentrator, making the solar tent concentrator system very economically attractive for domestic and commercial combined heat and power applications.

Small tent modules can quickly be installed in large numbers to create large solar farms. The tents are collapsible and can be transported in a similar fashion to a backpacking tent and therefore be useful to military personnel on missions or for recreational uses in remote areas.

Very fast development, commercialization and up scaling will enable distributed applications beyond basic domestic and commercial heat and power such as, but not limited to: 1) electricity for water pumping, 2) heat and electricity for water desalination, 3) heat and electricity for water demineralization, 4) heat for thermal water disinfection, 5) electricity for UV water disinfection, 6) heat and electricity for solar driven liquid fuel production by the converting CO2 or hydrocarbons, 7) heat for agricultural food and biomass drying, 8) heat for coal drying, 9) light concentration for photocatalysis of waste waters to remove pesticides and organics, 10) light concentration for photocatalysis of photolyte to produce hydrogen, 11) heat and electricity to drive solar driven desiccant air cooling, 12) heat and electricity to produce water from the atmosphere by adsorption using desiccant and or electro-static condensation technology, 13) heat to drive a Stirling engine, Organic Rankine Cycle, Steam or other engine to convert thermal energy to electrical energy, 14) heat and electricity to produce ammonia for energy storage or manufacture of fertilizer, 15) heat and electricity to produce sodium metal or zinc-oxide by molten electrolysis for energy storage and as an economic way to transport hydrogen by reacting the sodium metal with water and 17) pre-heating of air or fluids used in industrial processes such as, but not limited to: dry wall manufacturing, enhanced oil recovery and power generation.

As photovoltaic solar cells become more efficient, so will the solar tent concentrator system, further reducing the cost of the system.

The solar concentrating tents are collapsible and easily moved in the event of demand or land use changes. For example, in one day, an unskilled laborer with little to no prior training might install up to 100 kW of peak electricity derived from the solar tent concentrator modules. In a second day, the same laborer might remove the same 100 kW of solar concentrating tent modules and move them to a new plot of land.

### DRAWINGS—FIGURES

FIG. 1 is a left-side perspective view of a tent solar concentrator 1 with a parabolic reflector constructed in accordance with the invention.

FIG. 2 is an end view of the tent solar concentrator 1 with a parabolic reflector

FIG. 3 is a top view diagram of the solar concentrator

FIG. 4 is a side view of the solar concentrator

FIG. 5 is an end view of a parabolic tent solar concentrator with included solar tracking equipment.

FIG. 6 is a right-side perspective view of yet another alternate embodiment solar concentrating pup tent with a parabolic reflector constructed in accordance with the preferred embodiment.

REFERENCE NUMERALS

| | |
|---|---|
| 1 | solar concentrating tent |
| 5 | support post |
| 10 | support cord |
| 20 | bowed parabolic shaped beam |
| 30 | bowing cord |
| 40 | reflective thin film |
| 50 | middle support post |
| 60 | pivot cord |
| 70 | solar receiver |
| 80 | lateral receiver support rods |
| 90 | thin film transparent membrane |
| 100 | hoops |
| 110 | ground attachment point |
| 120 | floor |
| 140 | vertical receiver support member |
| 150 | tracking control line |
| 160 | tracking control lever |
| 170 | servo motor |
| 180 | servo controller |
| 215 | solar concentrating puptent |
| 220 | supporting guy wires |
| 230 | rigid tension member |
| 240 | puptent support poles |
| 260 | rigid parabolic ribs |
| 270 | transparent tent cover |

### DETAILED DESCRIPTION

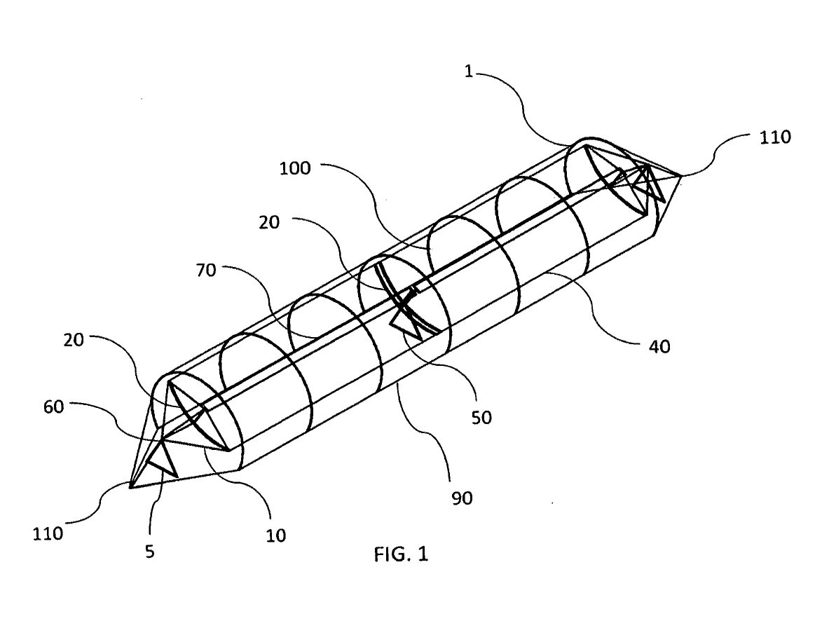

### Preferred Embodiments Contained in FIG. 1 through FIG. 5

FIG. 1 through FIG. 5 illustrate the preferred embodiment of this invention and is one example of how solar energy can be collected within a transparent tent and in no way limits the scope of this invention.

FIG. 1 is a right side perspective view of solar concentrating tent 1 constructed with a parabolic reflector in accordance with the invention. The end most points of the concentrator have ground attachments 110 that create tension forces supporting two separate structures of the solar concentrator. In a tent like manner, the first structure supported under tension is the non-concentrating outer thin film transparent membrane 90 that is further given shape by hoops 100 placed at periodic intervals along the length of the solar concentrating tent 1. A second interior structure supported under tension is the solar concentrator's reflective thin film 40 that is attached at both ends to bowed parabolic shaped beams 20 that are secured to a plurality of support cords 10. The plurality of support cords 10 are joined to a pivot cord 60 at each end of the concentrator while being held off the ground with support posts 5. The support posts 5 translate the tension forces from the reflective thin film 40 through the pivot cord 60 onto the ground attachments 110 at both ends of the tent. The reflective thin film 40 is further supported lengthwise at the center of the concentrator by a middle support post 50.

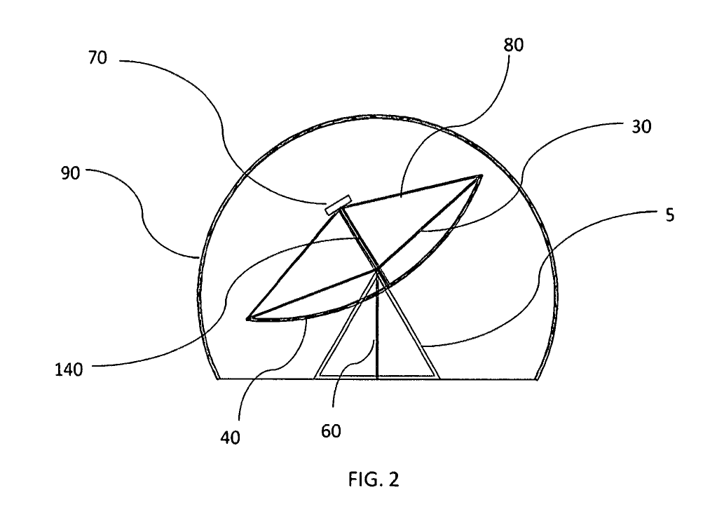

FIG. 2 is an end view of the tent solar concentrating tent 1 with parabolic reflector illustrating the solar receiver 70 attached to the reflective thin film 40 assembly through lateral receiver support members 80 and vertical receiver support members 140. The shape of the reflective thin film 40 is defined by the bowed parabolic shaped beam 20 shown in FIG. 1. The bowed parabolic shaped beam 20 is kept bent by a bowing cord 30 shown in FIG. 2. The reflective thin film 40 together with the solar receiver 70 are balanced and free to rotate about a common pivot point defined by the top of the support post 5.

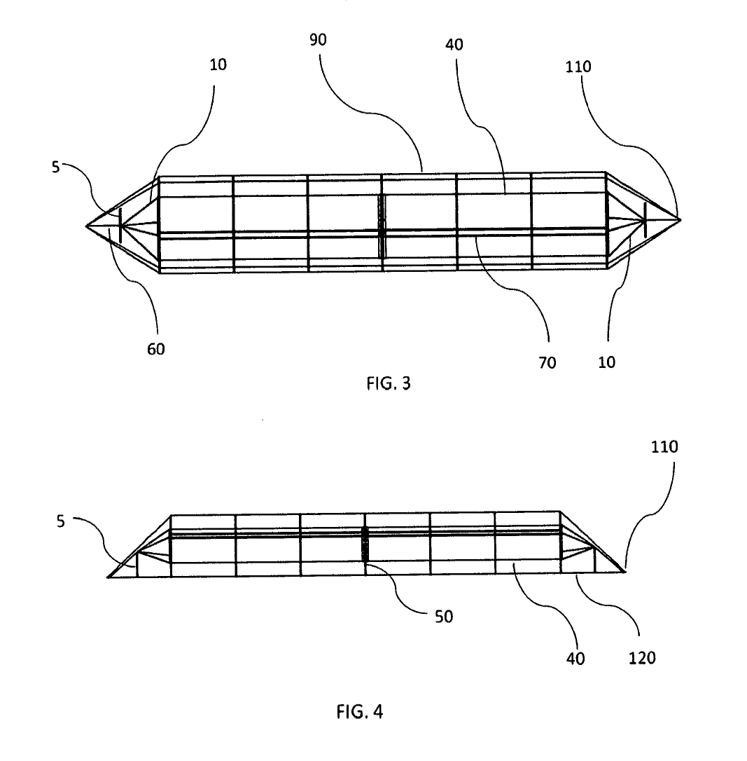

FIG. 3 is a top view of the tent solar concentrating tent 1 with a parabolic reflector and further illustrates the ability of sunlight to travel through the thin film transparent membrane 90 and to be reflected off the reflective thin film 40 and then be focused upon the solar receiver 70.

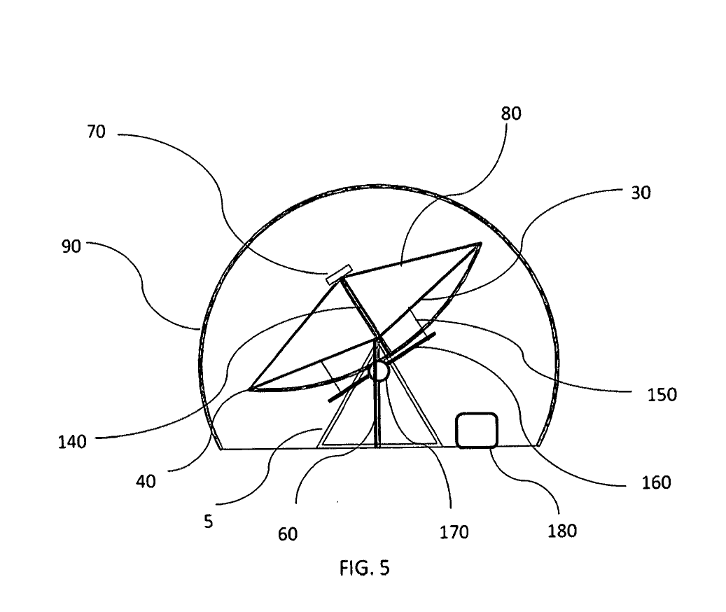

FIG. 4 is a side view of the tent solar concentrating tent 1 with a parabolic reflector showing the bottom of the concentrator floor 120. Together with the outer thin film transparent membrane 90 and the floor 120 the two joined membranes create a weather sealed environment to resist rain, wind, dust, hail, snow and unwanted flora, fauna and creatures from entering the tent like structure.

FIG. 5 is an end view of the preferred embodiment of the tent solar concentrator in FIG. 1 through FIG. 4 that includes solar tracking equipment. As light passes through the thin film transparent membrane 90, it reflects off the reflective thin film membrane 40 and is focused upon the solar receiver 70. In order for the light to be focused upon the solar receiver 70, the entire thin film transparent membrane 90 and receiver must rotate about a common pivot point in order to follow the path of the sun in the sky. The solar receiver 70 and thin film transparent membrane 90 are suspended in air about a common point defined by support post 5. Continuous tracking of the sun is achieved by small forces acting on the bowing cord 30 to initiate rotation in either direction to maximize the amount of light reaching the sensors embedded in the solar receiver 70. A tracking control line 150 is attached to the bowing cord 30. Forces act on the tracking control line 150 through a tracking control lever 160. The motion of the tracking control lever 160 acts in a rotational fashion by being connected to the servo motor 170. The servo motor 170 is electrically connected and controlled by the servo controller 180. The servo controller 180 senses opto-electronic signals from the solar receiver 70 and guides the servo to rotate, moving the tracking control lever 160 and putting a very slight downward force on the tracking control line 150 to continuously point the reflective thin film toward the sun.

### (1) Outer Thin Film Transparent Membrane

In the above examples, the tent's stretched outer thin film transparent membrane 90 can be made of several types of durable and optically clear thin sheeted plastics to include, but are not limited to polycarbonate or fluoro-polymers. Fluoro-polymers have a lifetime of approximately 30 years, and are transparent to UV radiation. The thickness of the material can range from 0.1 mils to 20 mils or more, and preferably around 5 mils. The tent's stretched outer thin film transparent membrane 90 is made up of panel sections joined by seams. The seam joining technology can use any common available methods employed to include but are not limited to, sewing, heat sealing, and ultrasonic welding. The cylindrical or closely parabolic form formed from the bent stick hoops 100 efficiently fit to the concentrator swept shape inside the tent. Internal and external guy wires can be added for additional support to aid in resistance to wind. The enclosed embodiment is convenient to reduce wind loading but numerous shapes known in the art of making tents can be employed as long as reflector and solar receiver 70 inside the tent can track the sun throughout the course of the day by rotating at least by approximately 47 degrees if oriented lengthwise in an East-West or 180 degrees if oriented North-South. Solar collection will be better in a North-South orientation and better yet if it also inclined on a slope toward the sun. The height of the solar concentrating tent 1 is primarily constrained by wind loading considerations and can range from less than 0.5 meters in height width to not larger than 2 meters in height in order to withstand a 50 mph sustained wind. Where the height of tent is made less than 2 meters, the length of the solar concentrating tent 1 is not constrained by wind loading and can be made as long as allowed by land use and desired power output and or convenience of installation. While the solar tent system can be used as standardized modules, they may also be joined through zipping or clipping into longer lengths and joined side-by-side to make solar farms. As the length increases beyond one reflective thin film 40 sheet in the range of 2 to 3 meters, additional middle support posts 5 are required at the termination of each reflector to maintain a parabolic shape with moderate tension forces necessary to load the reflective thin film 40 to a useful proportion of its load carrying capacity. Greater tension gives greater focusing ability and tracking accuracy, such that forces on the thin film is determined by film's design stress multiplied by its thickness times its width. Ground attachment points 110 can be anchored to the earth by means known in the art for securing tents during long term placement to include, but not limited to: long stakes, pounded posts, sand bags, and buried tent edges. The solar tent concentrator can also be mounted on walls, roofs, fences, base frames and awnings by nailing, screw down or other methods known in the art of building construction.

### (2) Solar Concentrator Inside Transparent Tent

In the preferred embodiment, the stretched thin film reflective membrane 40 inside the tent can be made of several types of thin film plastics to include, but not limited to Mylar, polypropylene and polycarbonate coated in such a manner to have a reflective mirror finish. Thin metal foils of aluminum can also be used in a stretched configuration as well and formed into parabolic shapes but do not have the reflective properties of reflective Mylar, for example. Thicknesses of the films can range from 0.1 mil to 15 mils or more and preferably be closer to 5 mils. The film thickness increases the overall reflective membrane's weight and thus requires more tension at the ground attachment points 110 in order to maintain a parabolic shape. While thinner films are less massive, and therefore require less tension, they tend to cause significant wrinkles and thereby reduce optical concentration levels. 3 to 5 mil thickness films work well and strike a balance between wrinkle formation and required tension. The stretched thin film reflective membrane 40 can be attached to the bowed parabolic shaped beams 20 by several methods. A convenient method of attachment is to wrap the plastic film around the beam and back onto itself creating a pocket. Heat can be applied along the double layer of folded material to create a strong seam able to resist tension forces on the membrane. Another viable approach of attachment is to create a pocket from the same or different material and sandwich the thin film reflective membrane 40 between two films. This may be done by wrapping a separate piece of film around the parabolic shaped beams 20 forms a pocket that can be double sticky taped and thread sewn to make a strong seam. Yet another method is to heat seal a bent over plastic strip onto the end of the thin film reflective membrane 40 and then clip it over the edge of the bowed parabolic shaped beam 20 made from a formed thin galvanized steel end rib. Other joining methods known in the art are possible with the constraint being that no wrinkles result in the thin film reflective membrane 40 as a result of the attachment method chosen.

### (3) The Solar Receiver

The solar receiver 70 will transform incoming light concentrated upon it to produce electricity and or heat. Alternatively the solar receiver 70 can channel focused light to drive photocatlytic reactions within a liquid or gas phase channel to produce high value hydrocarbon liquids, chemicals and purified water.

### (3-a) Solar Thermal Receiver

In an implementation where the solar receiver 70 heats water or oil in a tube, such fluid will flow through a square, circular pipe or rectangular channel of approximately ½ to 1″ inch width. The receiver pipe can be made of steel or aluminum with a low reflectivity surface and large ability to absorb heat. The concentrating pipe may also be contained within a vacuum glass tube to further increase its heat retaining and insulation capabilities that are well known in the art.

### (3-b) Combined Photovoltaic and Solar Thermal Receiver

Where photovoltaic cells are attached to the solar receiver 70, silicon based solar cells with concentrated light upon them will require either air, water and or other methods of cooling to maintain reasonable photon to electrical conversion efficiencies. Many methods of cooling photovoltaic cells by air or water methods are known to those skilled in the art and can be implemented using thermally conductive materials and high surface area heat transfer methods. Polycrystalline and mono-crystalline solar cells can efficiently be operated under 5 to 20 sun concentrations, with photovoltaic cells made from Type III-V semi-conductor materials operating under 50 to 1000 sun concentrations with the aid of secondary optics.

One preferred approach is to construct a combined photovoltaic and thermal receiver using a rectangular or square channel made of thin walled aluminum to produce hot water and electricity. In an example 15 sun concentrator, a rectangular aluminum channel ranging from ½″ to 3″ in height, and preferably no more than ¾″ in width can be used with the invention. The aluminum channel must be able to contain and allow flow of water and glycol and be rigid enough over the length of the solar concentrator tent to act as a substrate to attach the crystalline solar cells onto. Poly and mono-crystalline solar cells can be trimmed by YAG laser to accommodate the width of the solar receiver and be attached directly to the aluminum channel substrate. Provided the aluminum substrate has been coated with a suitable insulating material, such as a thin polyurethane spray or other suitable dielectric coating, solar cells may be adhered or laminated directly onto it. An additional layer of thin plastic laminate can be applied to the aluminum tube to ensure electrical separation of the solar cells from the substrate. The additional plastic film may advantageously contain printed electrodes for transferring electrical current. Poly and mono-crystalline solar cells attached to the ½″ to 3″ wide substrate can be advantageously connected in series to increase the voltage. As an example implementation, a 6″×6″ inch wide mono-crystalline solar cell containing three front bus bars may conveniently be trimmed by YAG laser into 1″×3″ strips, with each containing a front bus bar tab down the center. When the solar cells are wired in series and laminated lengthwise to one side of a 1 inch by 1 inch square piece of aluminum tube of approximately 12 feet in length, a cascaded voltage of almost 24 volts can be achieved. Any length can be chosen but is a useful example. Cooled water and or glycol solution are flowed through the aluminum tube while operating the solar cells under concentrated sun light conditions to reduce their temperatures to within their normal operating limits. By utilizing both the electricity and hot water generated from the solar tent concentrator system, solar conversion efficiencies in excess of 50% can be achieved. It is also well known by those skilled in the art that when concentrating light on poly and mono-crystalline solar cells, internal resistance losses within cells can cause voltage drops to occur, reducing power output at high currents. It is preferable to use poly and mono-crystalline solar cells with a low series resistance when using light concentrations above 3 sun concentration. Poly and mono-crystalline solar cells with front and back contacts are improving over time at handling higher currents with fewer series resistance losses. However, back-contact only solar cells are particularly well suited for light concentrations at 7 to 20 suns as they reduce photon shadowing along with having a low series resistance. Sunpower, Inc. and Solland Inc. are example suppliers of back-contact only mono and poly-crystalline solar cells respectively. Trimming commercially available solar cells to smaller sizes when concentrating has the additional benefit of further reducing series resistance and increasing voltage to allow for greater power transfer.

### (3-c) Photocatalytic Solar Receiver and Reactor

Where photocatalysis occurs in the solar receiver 70, light is further focused within optically transparent electrolytic fluid channels containing photo catalysts of various possible metal oxides or metals and electrolyte to achieve photo-oxidation. Example photo-catalysts include but are not limited to Titanium Oxides, Tungsten, Indium Phosphide, Iron Oxides and nano-particle encapsulation with various other metal or inorganic materials. Electrolytes can include, but are not limited to, various aqueous solutions that contain bases such as sodium hydroxide (NaOH) as well as acids to include HBr and HI. Photo catalyzed electrolytes will liberate gases such as hydrogen, chlorine and bromine Waste water containing organics, such as pesticides and bacteria in the presence of concentrated light and a proper photocatalyst will be purified and toxins neutralized. The solar receiver 70, may also allow for photo catalysis in the gas phase allowing carbon dioxide to be upgraded to methane, methanol or other liquid hydrocarbons for example in the presence of titanium nano-tubes. Similarly methane can be upgraded to methanol using photo-active catalysts. Reactor plastic choices would be dependent upon the electrolyte and gases chosen and could include, but not limited to polycarbonate and fluoro-polymers. Expelled halogen reactants from the solar receiver 70 may be stored for later use in energy production with a fuel cell such as with bromine and hydrogen to produce electricity. Alternatively, and known to those skilled in the arts, excess halogenated components such as bromine may be used to produce chemicals and or liquid fuels using condensation reactions of methyl bromine in the presence of metal oxides.

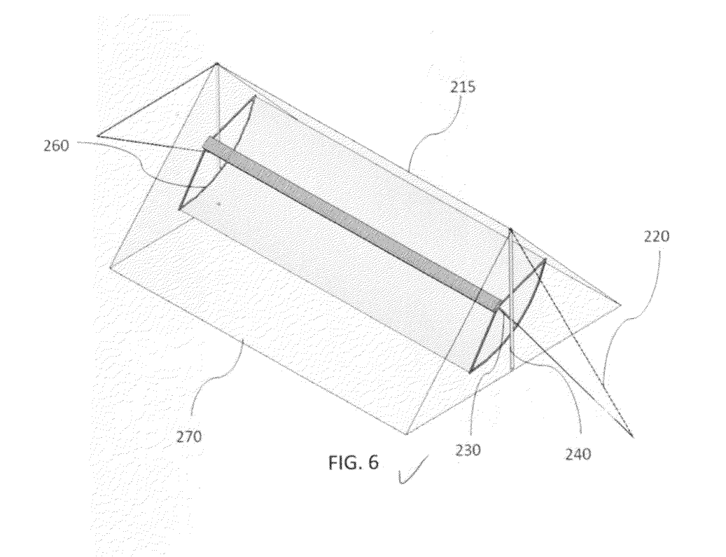

### Alternate Embodiments Contained in FIG. 6

FIG. 6—This figure is a perspective of a solar concentrating puptent 215 and is an alternative embodiment to the solar concentrating tent 1 described in the preferred embodiment. The solar concentrating puptent 215 is constructed and operates identically to the preferred embodiment of this invention with several exceptions: 1) The transparent tent cover 270 is supported in a traditional architecture by puptent support poles 240 with supporting guy wires 220, 2) The thin film parabolic reflector is stretched and attached exclusively to the rigid parabolic ribs 260 with methods already described in the preferred embodiments, 3) The rigid parabolic ribs 260 are held suspended and under tension by attachment to the rigid tension members 230, 4) The rigid tension members 230 are connected to the puptent support poles 240 to keep the parabolic reflector suspended and transfer load to ground attachment points and 5) The solar concentrating puptent 215 is also attached to the ground, roof, fence or wall at the lower four corners of the tent.

There are numerous methods of collecting solar energy within a transparent tent that can be envisaged by one skilled in the art. Aforementioned embodiments for how to collect the solar energy inside the tent should not be construed in anyway limit the scope of this invention.

### OPERATION

A reflective film is stretched between actuated parabolic ribs so as to form a lightweight and low cost parabolic trough solar concentrator. The solar concentrator is erected inside a transparent low cost tent that shields and protects it from wind, rain, hail and dusts. A water and or air cooled photo voltaic strip along the focal point generates electricity. Alternatively air, water or oil is heated in a tube along the focal point to transfer heat for space heating, drying, electricity generation, absorption cooling, water disinfection and other potential applications. A microcontroller controls a servo, which rotates the parabolic trough solar concentrator so that it tracks the sun, keeping the sun focused on the receiver.

The tent like construction allows the solar concentrator system to be quickly and easily pitched and packed away again. In addition to pitching the solar concentrator system on the ground as per a normal tent, it is possible to pitch it on flat and sloped roofs. It is also possible to pitch it on the vertical walls of houses and buildings. It would even be possible to pitch the system on difficult terrain including cliff surfaces if desired. Unlike some solar concentrator systems this system is not constrained to horizontal surfaces, though anchoring methods appropriate for the surface do need to be used. Like a solar panel, the solar concentrator tent structure should optimally be oriented towards the sun at an elevation angle that maximizes solar collection. This favors sloped surfaces that face the equator, ground applications might even grade the surface to suit, however site convenience and cost will likely dominate such considerations in most cases.

The construction systems and techniques as used to make tents, kites and sails can be used to construct both the transparent tent and the stretched reflective parabolic trough concentrator. The respective plastic film seams can be taped and sewn, pockets for sticks added and reinforcements applied as needed. Standard stick, pole or batten materials can be selected, whether for cost, lightweight or convenience and bridles and stay lines added. Repairs could be readily made by the many people the world over who are familiar with such repair techniques. Heat and ultrasonic welding techniques might also be employed upon the plastic films, enabling greater automation in manufacture and potentially lower cost and greater accuracy. Heat forming techniques might also be applied in some circumstances to improve shape.

The parabolic ribs used to define the shape of the reflective film concentrator can be constructed using simple fiberglass sticks bowed with a chord; however, rigid ribs and other materials are also possible, to include rigidly formed steel or aluminum ribs as likely possibilities. The receiver is also supported from these ribs. The receiver itself might consist of an aluminum tube on which solar cells are mounted and through which cooling water is flowed. Air-cooling is also possible and one or more small cooling fans might be mounted along the receiver. For air cooling a specialist aluminum extrusion might be desired for the receiver that includes a multitude of cooling fins. The air-cooling solution may also contain a vent in the tent to allow cool air to enter from outside, so as to lower the temperature of the air inside the tent which is used for cooling. Hybrid air and water-cooled receiver designs are further possible and perhaps desirable for some combined heat and power applications where heat and power may wish to be independently variable. While transferring electricity from the moving receiver is relatively trivial using flexible wires to pass over the parabolic trough concentrator pivot, hot water is a little harder to transfer, although with care flexible tubing can be used.

There are numerous conventional ways of controlling and actuating the tracking of a parabolic trough solar concentrator. A simple approach in this case is to use a standard micro controller to operate a servo that rotates the concentrator to follow the sun. Knowing time and servo position it is possible to track the sun, however solar cell power feedback may be desired for more accurate tracking. Various other sensors might also be used to improve accuracy. Low cost model servos can be used in many circumstances, as the power required can be very low and the environment can be relatively benign, although greater accuracy and longevity may be desired. More elaborate actuation systems and even thermo actuators might be used. Although one advantage of electronic actuation is the capacity to point the concentrator away from the sun, effectively governing the power output and even turning the system off if desired.

1. In a solar concentrating and energy conversion structure resembling a transparent tent and comprising:
an outer thin film transparent membrane of said structure formed and stretched over a plurality of minimal internal framing members, said thin film transparent membrane is supported and kept under tension by attachment points at opposite ends of said structure, inside said structure is a light weight tensegrity solar collecting and reflective focusing surface with said reflective focusing surface suspended to allow rotational motion, attached to said reflective focusing film at a predetermined distance is a solar receiver, whereby
(a) light enters said solar collecting and energy conversion platform through said outer transparent membrane, and
(b) said reflective focusing surface is continuously pointed in the direction of said light with a tracking mechanism, and
(c) said light reflects off said reflective focusing film and is focused onto said solar receiver, and
(d) said solar receiver converts light into heat and or electricity, and
(e) said solar receiver may optionally contain photocatalyst and transparent channels allowing photons to interact and oxidize reactants in either a liquid or gas phase, and
(f) the tent-like said structure is transportable and may be erected in minutes without substantial skill or ground surface grading or improvements and,
(g) the transportable tent-like said structure may optionally be produced to withstand 100 km/hour winds.
